(19) United States
(12) Patent Application Publication
(10) Pub. No.: US 2007/0090380 A1
(43) Pub. Date: Apr. 26, 2007

(54) Image sensor structure with a connector

(76) Inventor: Chung Hsien Hsin, Hsinchu Hsien (TW)

Correspondence Address: PRO-TECHTOR INTERNATIONAL SERVICES, 20775 NORADA CT., SARATOGA, CA, 95070, US

(21) Appl. No.: 11/256,370

(22) Filed: Oct. 20, 2005

(51) Int. Cl. H01L 33/00

(52) U.S. Cl. 257/98

(57) ABSTRACT

An image sensor structure with a connector includes a substrate having an upper surface, which is formed with a central region and first electrodes arranged at the periphery of central region, and a lower surface is formed with second electrodes corresponding to electrically connect the first electrodes. A frame layer is arranged at the upper surface of the substrate, so that a cavity is formed between with substrate and frame layer. A chip is mounted at the central region of the upper surface of the substrate and is located within the cavity. A plurality of bonding pads is formed at the periphery of the chip. A plurality of wires are electrically connected the bonding pads of the chip to the first electrodes of the substrate, so that the signal from the chip is transmitted to the second electrodes of the substrate through the first electrodes. The transparent layer is covered on the frame layer to encapsulate the chip. The connector is mounted at the lower surface of the substrate for electrically connecting to the electrical element.

### BACKGROUND OF THE INVENTION

1. Field of the Invention

The invention relates an image sensor structure with a connector, and particular to a structure for directly electrically connected to a electrical element, the manufacturing cost may be decreased, and the reliability of the image sensor may be promoted.

2. Description of the Related Art

Referring to FIG. 1, it is an image sensor structure includes a substrate 10, a frame layer 18, a photosensitive chip 26, a plurality of wires 28, and a transparent layer 34.

The substrate 10 has a first surface 12 on which plurality of first electrodes 15 are formed, and a second surface 14 on which plurality of second electrodes 16 are formed. The first electrodes 15 are corresponding to electrically connect to the second electrodes 16 by the conductive wires 17, which are located at the side of the substrate. The frame layer 18 has an upper surface 20 and a lower surface 22 adhered to the first surface 12 of the substrate 10 to form a cavity 24 together with the substrate 10. The photosensitive chip 26 is arranged within the chamber 24, and is mounted to the first surface 12 of the substrate 10. Each wire 28 has a first terminal 30 and a second terminal 32. The first terminals 30 are electrically connected to the photosensitive chip 26, and the second terminals 32 are electrically connected to the first electrodes 15 of the substrate 10. The transparent layer 34 is adhered to the upper surface 20 of the frame layer 18.

Please referring to FIG. 2, it is a schematic illustration showing an image sensor structure, the second electrodes 16 of the substrate 10 is connected to a flexible board 36, which is arranged with a connector 38 by SMT for electrically connected to a electrical element.

### SUMMARY OF THE INVENTION

An objective of the invention is to provide an image sensor structure with a connector, and capable of decreasing the manufacturing cast of the image sensor.

An objective of the invention is to provide an image sensor structure with a connector, and capable of increasing the reliability of the image sensor package.

To achieve the above-mentioned object, the invention provides a substrate having an upper surface, which is formed with a central region and first electrodes arranged at the periphery of central region, and a lower surface is formed with second electrodes corresponding to connect the first electrodes. A frame layer is arranged at the upper surface of the substrate, so that a cavity is formed between with substrate and frame layer. A chip is mounted at the central region of the upper surface of the substrate and is located within the cavity. A plurality of bonding pads is formed at the periphery of the chip. A plurality of wires are electrically connected the bonding pads of the chip to the first electrodes of the substrate, so that the signal from the chip is transmitted to the second electrodes of the substrate through the first electrodes. The transparent layer is covered on the frame layer to encapsulate the chip. The connector is mounted at the lower surface of the substrate for electrically connecting to the electrical element.

### BRIEF DESCRIPTION OF THE DRAWINGS

FIG. 1 is a cross-sectional view illustration showing a conventional image sensor structure.

FIG. 2 is a schematic illustration showing a conventional image sensor structure.

FIG. 3 is a first schematic illustration showing an image sensor structure with a connector of the present invention.

FIG. 4 is a second schematic illustration showing an image sensor structure with a connector of the present invention.

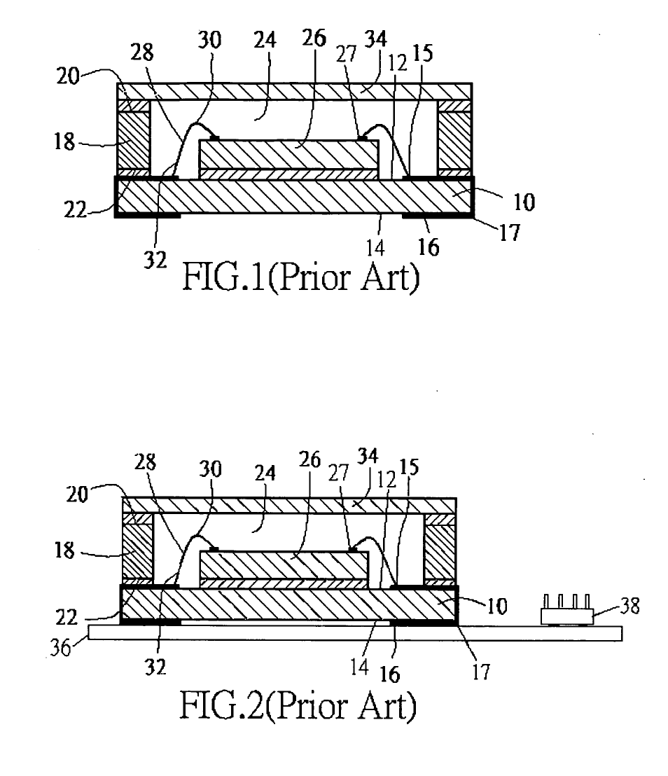

### DETAILED DESCRIPTION OF THE INVENTION

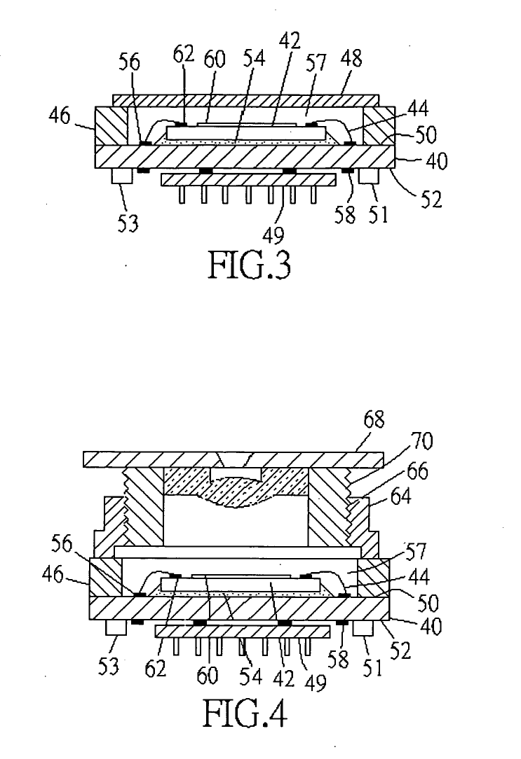

Please refer to FIG. 3, an image sensor structure with a connector of the present invention includes substrate 40, a chip 42, wires 44, a frame layer 46, a transparent layer 48 and a connector 49.

The substrate 40 has an upper surface 50, which is formed with a central region 54 and at the periphery of central region 54 is formed with first electrodes 56, and a lower surface 52 is formed with second electrodes 58 corresponding to electrically connect to the first electrodes 56, and a passive electrical element 51 and an active electrical element 53 are formed at the lower surface 52 of the substrate 40

The frame layer 46 is arranged at the upper surface 50 of the substrate 40, a cavity 57 is formed between with the substrate 40 and the frame layer 46.

The chip 42 is mounted at the central region 54 of the upper surface 50 of the substrate 40 and is located within the cavity 57, a plurality of bonding pads 62 are formed at the periphery of the chip 42.

The plurality of wires 44 are electrically connected the bonding pads 62 of the chip 42 to the first electrodes 56 of the substrate 40, so that the signal from the chip 42 is transmitted to the second electrodes 58 of the substrate 40 through the first electrodes 56.

The transparent layer 48 is covered on the frame layer 46 to encapsulate the chip 42.

The connector 49 is mounted at the lower surface 52 of the substrate 40 for electrically connecting to a electrical element.

Please refer to FIG. 3, a lens holder 64 having a internal thread 66 is mounted on the transparent layer 48, a lens barrel 68 having a external thread 70 is threaded to the internal thread 66 of the lens barrel 64 to be a image sensor module.

While the invention has been described by the way of an example and in terms of a preferred embodiment, it is to be understood that the invention is not limited to the disclosed embodiment. On the contrary, it is intended to cover various modifications. Therefore, the scope of the appended claims should be accorded the broadest interpretation so as to encompass all such modifications.

What is claimed is:

1. An image sensor structure with connector, the structure for electrically connecting to an electrical element comprising
a substrate having an upper surface, which is formed with a central region and first electrodes arranged at the periphery of the central region, and a lower surface formed with second electrodes corresponding to electrically connect the first electrodes
a frame layer arranged at the upper surface of the substrate, a cavity formed between with substrate and frame layer
a chip mounted at the central region of the upper surface of the substrate and located within the cavity, a plurality of bonding pads formed at the periphery of the chip;
a plurality of wires electrically connected the bonding pads of the chip to the first electrodes of the substrate, so that the signal from the chip transmitted to the second electrodes of the substrate through the first electrodes
a transparent layer covered on the frame layer to encapsulate the chip; and
a connector mounted at the lower surface of the substrate for electrically connecting to the electrical element.

2. The image sensor structure with a connector according to claim 1, wherein the lower surface of the substrate is formed with passive electrical element and active electrical element.

3. The image sensor structure with a connector according to claim 1, wherein a lens holder and a lens barrel are formed at the transparent layer to form a module structure.
